(19) United States
(12) Patent Application Publication
(10) Pub. No.: US 2008/0314437 A1
(43) Pub. Date: Dec. 25, 2008

(54) Multiple Heliostats Concentrator

(76) Inventor: Amnon Regev, Haifa (IL)

Correspondence Address: YORAM TSIVION, P.O. BOX 1307, PARDES HANNA, 37111, IL

(21) Appl. No.: 12/093,717

(22) PCT Filed: Nov. 15, 2006
(86) PCT No.: PCT/IL2006/001321

§ 371 Date: May 15, 2008

Related U.S. Application Data
(60) Provisional application No. 60/597,214, filed on Nov. 17, 2005.
(60) Provisional application No. 60/843,519, filed on Sep. 11, 2006.

(51) Int. Cl. H01L 31/042

(52) U.S. Cl. 136/246

(57) ABSTRACT

A multi heliostat concentrating (MHC) system for utilizing sun energy has at least on MHC module. A MHC module has at least one optical concentrator having a focusin reflective surface, aperture and an optical axis. A plurality of heliostats, which are preferably located symmetrically relative to the optical axis of an optical concentrator simultaneously reflect sun radiation towards its aperture. Flux error correcting an flux homogenizing device disposed at the focal region of an optical concentrato provides for further concentrating and homogenizing the flux of the focused su radiation. A receiver preferably comprising concentrated photovoltaic cells and a optional passive heat-sink provides for efficiently and economically generatin electrical power.

### FIELD OF THE INVENTION

The present invention relates generally to concentrated solar energy and more specifically to a method and apparatus for collecting, concentrating and converting solar energy to electrical energy.

### BACKGROUND OF THE INVENTION

Concentrated solar power holds a great promise to enable energy applications that are economically viable. By employing radiation-collecting surfaces to collect and concentrate the sunlight, various thermal, electrical and chemical applications can harness solar energy into practical and economical use.

Concentrator Photovoltaic Cells (CPV cells) for example enable solar electricity at prices that are competitive with electricity generated from fossil fuels. CPV are more efficient than other photovoltaic cells. Also, by using concentrated sunlight to illuminate the CPV cells, most of the sunlight collection surface is made from relatively inexpensive optical materials—such as glass or plastic. Thus using CPV cells may lower, by several orders of magnitude, the cell area that is required to produce a unit of electrical energy, compared to non-concentrated photovoltaic cells. The higher the concentration ratio, the less cell area needed.

Concentrating the sun requires an optical system to be a part of a Concentrated Solar Power system. Also, high concentration applications such as CPV cells require uniform concentrated flux, therefore imposing strict requirements on the optical system in terms of design and manufacturing accuracy. Also, the CPV cells convert only a portion of the energy they receive from the optical system to electricity. The rest of the energy is converted to heat. This waste heat must be dissipated from the cells quickly enough to prevent a rise in the cell temperature, a decrease in the cell efficiency and possible damage to the CPV cells. Thus a CPV cell system also requires a cooling system for the cells.

Numerous designs for concentrating solar power systems are known. However, none of the existing designs enable a concentrated solar power system that meets the price-performance targets that make solar energy economically competitive. Existing designs of concentrated solar power are also not durable enough and are relatively hard to maintain. Following are indicated some drawbacks of the currently available technologies typically employed in such concentrated solar power systems:
Fresnel lens based CPV modules have relatively expensive optics, are hard to clean, and have multiple failure points in the cell packaging
Parabolic dish systems—have relatively expensive optics, are hard to clean, and have a relatively high profile above the ground level.
Parabolic mini-dish systems—have complex cell arrays, have complex optics, have a relatively high profile above the ground level, and have multiple failure points in the cell packaging schema.
Parabolic trough systems similarly to Fresnel trough systems have relatively expensive optics, have relatively low concentration ratios, and are hard to clean.

Therefore a concentrated solar power system that is compact and simple to produce, install, operate and maintain, at competitive costs relative to the electrical power systems utilizing fossil fuel is called for.

### BRIEF DESCRIPTION OF THE DRAWINGS

FIG. 1 schematically shows an isometric view of an exemplary optical subsystem of the present invention;

FIG. 2 is a segment of a ray-tracing map of an exemplary optical subsystem of the invention shown in a topside view;

FIG. 3 is a sectional view schematically showing a combined optical concentrator according to a preferred embodiment of the present invention;

FIG. 4A is a segment of a first exemplary ray tracing map shown within an optical concentrator according to a preferred embodiment of the present invention;

FIG. 4B is an enlarged detail of FIG. 4A;

FIG. 4C is a segment of a second exemplary ray tracing map shown within the same optical concentrator shown in FIG. 4B;

FIG. 4D is a segment of a third exemplary ray tracing map shown within the same optical concentrator shown in FIG. 4B;

FIG. 4E is a segment of a first exemplary ray tracing map shown within an optical concentrator according to another preferred embodiment of the present invention;

FIG. 4F is a segment of a second exemplary ray tracing map shown within the same optical concentrator shown in FIG. 4E;

FIG. 4G is a segment of a third exemplary ray tracing map shown within the same optical concentrator shown in FIG. 4E;

FIG. 4H is a segment of a first exemplary ray tracing map shown within an optical concentrator according to another preferred embodiment of the present invention;

FIG. 4I is a segment of a second exemplary ray tracing map shown within the same optical concentrator shown in FIG. 4H;

FIG. 4J is a segment of a third exemplary ray tracing map shown within the same optical concentrator shown in FIG. 4H;

FIG. 5A is a side looking view of a passive heat sink according to a preferred embodiment of the present invention;

FIG. 5B is a backside side looking view of the heat sink shown in FIG. 5A;

FIG. 6A is an isometric view of a mounted MHC module having one row of heliostats;

FIG. 6B is an isometric view of a mounted MHC module according to a preferred embodiment of the present invention;

FIG. 7 is a schematic layout of an MHC module having a stand-alone configuration;

### DETAILED DESCRIPTION OF THE PRESENT INVENTION

A multiple heliostat concentrator (MHC) system for utilizing sun energy is provided in accordance with the present invention. MHC system according to the present invention includes one or more MHC modules. Each MHC module consists of the following sub-systems: an optical system having a plurality of heliostats simultaneously directed towards a common optical concentrator; a receiver for converting the solar energy into heat for further utilization as is known, or directly converting the sun energy into electrical energy, such as by means of an array of concentrated photovoltaic (CPV) cells. A heliostat or a group of heliostats are provided according to the invention with one or two driving motors and a local controller providing for rotational tracking of the sun. A central controller, which is linked to all of the local controllers, synchronizes and controls the operation of the entire MHC system.

Optical Subsysatem

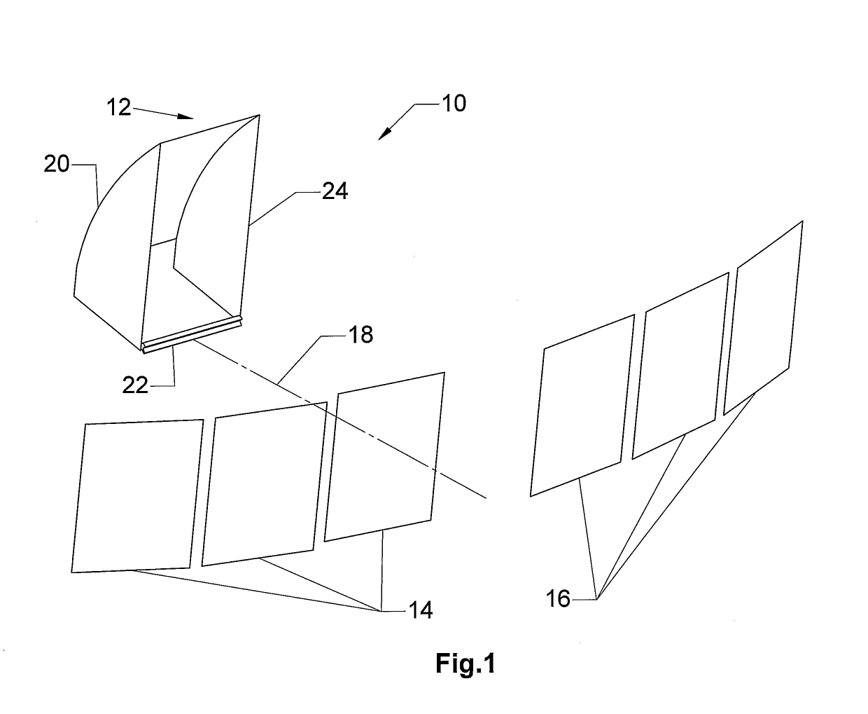

Reference is first made to FIG. 1 in which an isometric view of an exemplary optical subsystem 10 is schematically shown. Optical concentrator 12 faces two groups of heliostats 14 and 16 symmetrically disposed at both sides of optical axis 18 of optical concentrator 12. A single heliostat whose aperture has an axis of symmetry of reflection, which is such disposed that this axis is perpendicular and intersects the optical axis of the concentrator is in accordance with the present invention. An optical sub-system of the invention preferably has an even number of heliostats illuminating the same common optical concentrator 12. Planar heliostats are normally less expensive in production and maintenance and are therefore preferable according to the invention. Optical concentrator 12 has focusing reflective back 20, which is typically shaped as a parabolic cylindrical surface. Namely, such a surface is axially symmetrical whereat parabolas are formed when is sectioned by a series of parallel planes which are perpendicular to the axis of symmetry. A focus error correction and flux homogenising device (FECFHD) 22 is disposed at the focal region of focusing reflective back 20. Optical concentrator 12 further has according to a preferred embodiment of the present invention planar sidewalls 24 whose internal faces are reflective. Therefore focal intervals corresponding to radiation reflected by heliostats disposed aside from optical axis 18 are merged within a substantially small region along an almost linear interval, referenced hereinafter as focal interval, disposed across the inlet of FECFHD 22. Devices having a surface reflecting to the sun radiation into the same region are referenced hereinafter as heliostats.

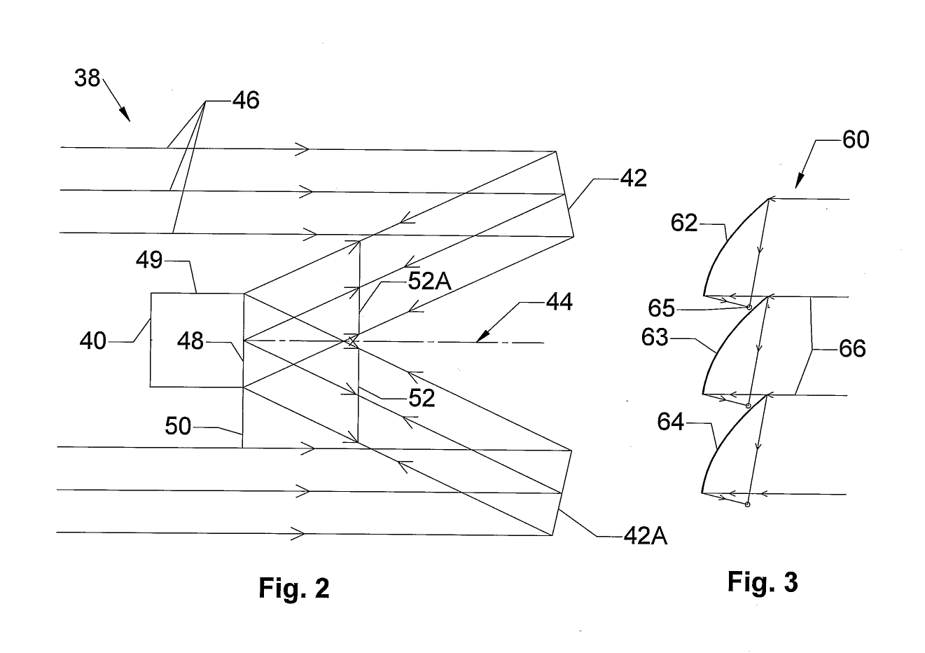

The effect of merging focal intervals corresponding to a number of illuminating beams respectively reflected from different heliostats can be better explained by reference to FIG. 2. In FIG. 2 a ray-tracing map is shown within a segment of an exemplary optical subsystem of the invention 38, which is schematically shown in a topside view. Optical concentrator 40 faces two heliostats 42 and 42A disposed at the opposing sides of its optical axis 44. Illuminating rays 46 are reflected by heliostat 42 onto the focusing reflective back wall of concentrator 40 thereby converged into a linear focus that partially coincides with interval 48. Interval 48 is located at a plane, which is behind the plane of the paper of FIG. 2. In a case in which sidewall 49 is absent the focal line extends along dashed interval 50. This focal line is schematically presented by interval 52 for the sake of simple description. Similarly the focal line generated by light reflected by heliostat 42A is presented by interval 52A. However an optical concentrator having two reflective sidewalls causes these two focal lines to be symmetrically folded and merged along interval 48.

Optical Concentrator

The focusing reflective back of an optical concentrator, such as having a parabolic cylindrical surface, provides for a significant concentration ratio due to the fact that it forms a focal region having a significantly low cross section encompassing the focal interval, which is closely located within a plane containing the optical axis of the optical concentrator. This concentration ratio is termed hereinafter by primary concentration ratio and it closely equals the ratio between the area of the aperture of the optical concentrator and the area of this cross section. An optical concentrator that is illuminated by a number of heliostats provides for concentration of the sunlight by a concentration ratio that is proportional to the multiplication of its primary ratio by the total area of the illuminating heliostats divided by the area of the aperture of the optical concentrator. The concentration ratio of an MHC module of the invention is further multiplied by respective cosine factors and a loss factor related to the accumulated losses along the optical paths of the concentrated radiation including tracking errors. The arrangement of the heliostats in an MHC module of the invention is preferably symmetrical such that each heliostat of a pair of symmetrically disposed heliostats illuminates the aperture of the optical concentrator at the same angle relative to its optical axis. The sidewalls of the optical concentrator are either planar or having converging curvatures such as parabolic. These sidewalls form an optical tunnel through which by a single or multiple reflection the foci of each heliostat are folded and merged along a common focal interval disposed across the inlet aperture of the FECFHD. Therefore by considering practical limitations of laying the heliostats in front of an optical concentrator a significant concentration ratio of several hundreds of suns is provided according to the present invention, as is further described infra. (A standard sun is defined by a radiating power of 850 watts per square meter.)

The walls of an optical concentrator according to the invention are typically made of metal such as polished and or reflective coated stainless steel. Plates of glass or plastic coated with a reflective material mounted onto supporting frames made of metal or plastic resins are acceptable as well. The reflective surfaces of heliostats of the invention are similarly made as is known.

Combined Concentrators

Normally the number and dimensions of the apertures of the heliostats are defined according to the present invention in accordance with the power requirements of the MHC system. Obviously the dimensions of the aperture of an optical concentrator comply according to the invention with the dimensions of the heliostats. Reference is now made to FIG. 3 in which a combined optical concentrator 60 consisting of three staggered optical concentrators 62, 63, 64 is schematically shown. Focal region 65 of concentrator 62 is located external to concentrator 63. Rays 66 indicates the overlapping of the illuminating beam and the combined apertures of the staggered concentrators 62-64. The effective aperture of a combined optical concentrator according to the present invention consists of all the apertures of the basic concentrator incorporated. A combined aperture of a combined optical concentrator is referenced hereinafter as the aperture of an optical concentrator and its effective area equals the sum of the areas of the apertures of the basic concentrator constituting it.

Similarly basic optical concentrators can be arranged according to the present invention by any arrangement. Preferable are one or two-dimensional arrays. In any of such arrangement the apertures of adjacent basic concentrators are laid as close as possible to each other and the areas of gaps if any are separating between them are minimized. The number of rows and or columns, namely the width and height of an array of concentrators comply with the respective dimensions of the heliostats illuminating it.

FECFHD

In order to compensate for inaccuracies in, or distortions of, the geometrical shapes and orientations of the optical components, such as the respective orientations, or the uniformity, of the reflective surfaces of the heliostats or optical concentrator; and/or inaccuracies in the positions of the optical components along the optical path; and/or inaccuracies in the sun tracking operation, a FECFHD is employed. A FECFHD of the invention is preferably an optical device having a relatively weak concentrating power and a wide acceptance angle. Such a device may be based according to the invention on refractive optical components such as having a transparent focusing lens incorporated with a waveguide in which multiple reflections along its sidewalls provide for homogenising the flux. Alternatively a non-imaging focusing reflective surfaces can be employed as well. A FECFHD provides for compensating shifts in the locations or distortions of the shapes of respective focal intervals corresponding to a number of heliostats directed to a common optical concentrator. Such shifts in the position of the focal intervals are originated by inaccuracies of respective positions and or orientations of the various heliostats relative to the optical concentrator. Distortions of the geometrical shapes of the reflective surfaces typically cause curving of the focal intervals and their broadening into regions having a width and volume. The wide acceptance angle of a FECFHD ensures that rays of impinging on the inlet of a FECFHD at relatively wide angles of arrival emerge from the FECFHD at relatively small angles of escape.

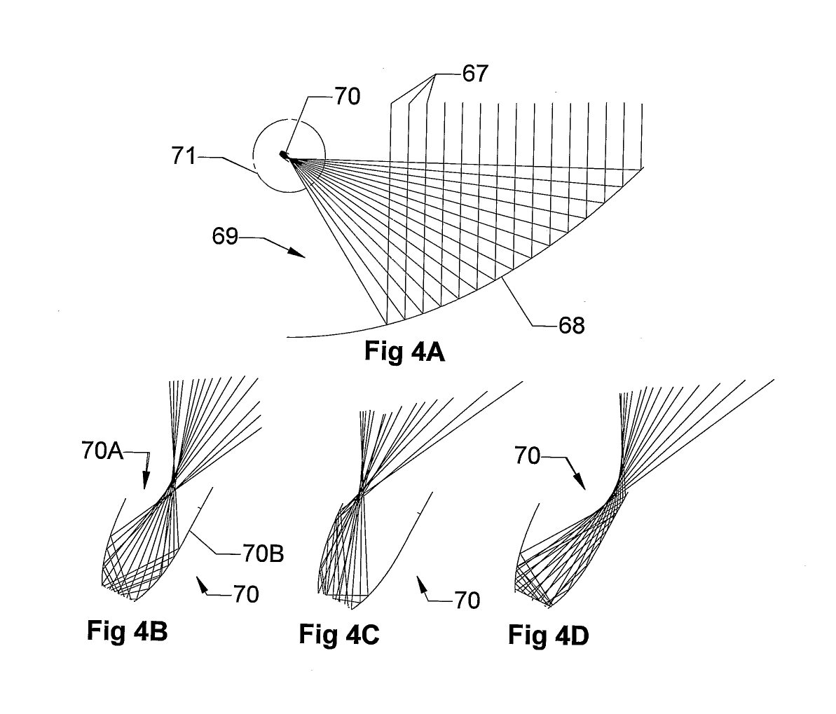

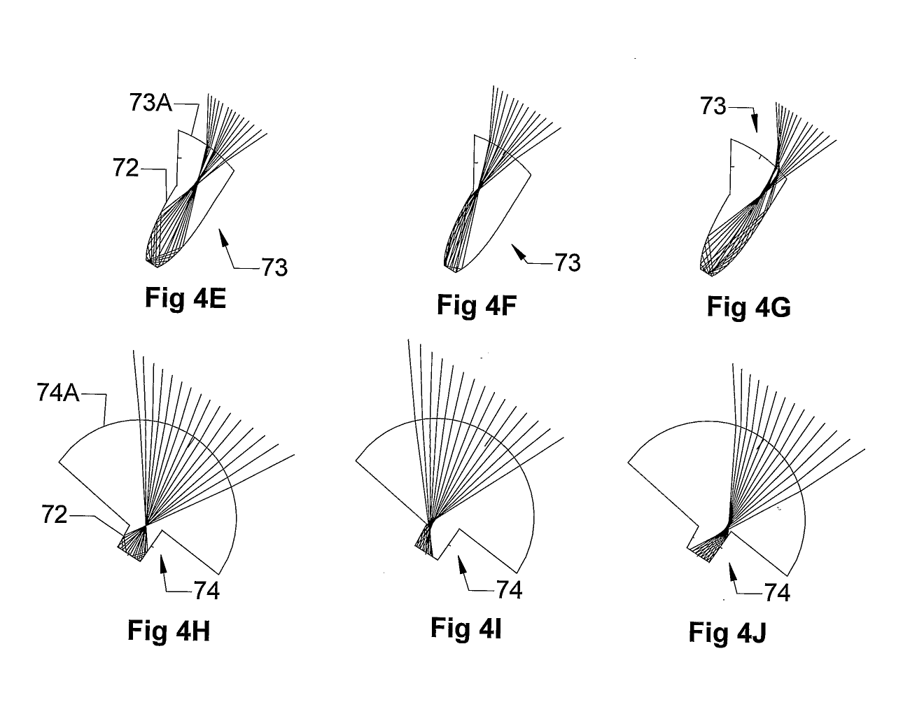

For better describing a FECFHD of the invention a reference is now made to FIGS. 4A through 4J in which various segments of ray tracing maps are respectively shown within optical concentrators according to different embodiments of the present invention. In FIG. 4A rays 67 impinging on the focusing reflecting back wall 68 of optical concentrator 69 are converged into the inlet of FECFHD 70. FECFHD 70 and the same map of ray tracing and in addition two other exemplary maps are respectively shown in more details in FIGS. 4B-4D. FECFHD according to this preferred embodiment 70 is shaped such a funnel. FECFHD inlet 70A, which is inclined relative to its axis, provides for a relatively wide acceptance angle when is such disposed that the lower end of the sidewall points away from the focusing reflective back side of the optical concentrator. The sidewall 70B is such concaved that an additional focusing is provided. Multiple reflections along sidewall 70B further provides for homogenizing the flux such that the maximal angle of escape is substantially smaller than the maximal angle of acceptance available.

In FIGS. 4E through 4J similar three exemplary ray tracing maps within FECFHDs according to two other preferred embodiments of the present invention are respectively shown. Both FECFHDs are made of transparent dielectric materials such as glass or plastic resins respectively having such refraction constants that total internal reflection is provided at their waveguide sections 72. In accordance with the first of these preferred embodiments FECFHD 73 has a parabolic cylindrical inlet 73A in which the parabolas are contained in planes parallel to the plane of the paper. The cross section of the waveguide section 72 is asymmetrically extended towards one side proximal to the inlet 73A such that a relatively wide acceptance angle is provided when the extended side is disposed away from the parabolic reflective back wall of the optical concentrator. A FECFHD according to the other preferred embodiment 74 has a cylindrical inlet 74A and a waveguide section 72 having a quadrangular cross section. The faces of an inlet of a FECFHD consisting of components based on refractive optics are optionally coated with anti-reflecting coating as is known.

Receiver

A receiver according to the invention is any device providing for converting a portion of the concentrated energy of the sun radiation into another form of energy that is further employable. An exemplary receiver according to the invention consists of a segment of pipe carrying a flowing fluid. Such heated fluid by the concentrated sun radiation can be further employed such as for inducing mechanical motion by energising a turbine. A segment of the surface of this pipe carrying the heated fluid constitutes the inlet of this receiver. Such receiver is mounted onto a mounting frame such that its inlet is centered within the focal range of the optical concentrator or at the outlet of a FECFHD when such device is present. Whether FECFHD is present or not the receiver inlet is such disposed that the portion of the concentrated sun radiation illuminating it is maximal.

A receiver according to a preferred embodiment of the present invention provides for directly converting a portion of the energy of the sun to electrical energy by means of CPV cell array. The number of CPV cells and the length of a linear CPV cell array complies with the concentration ratio of the respective optical subsystem of the MHC module. Such a receiver also includes means for dissipating waste heat from the CPV array. Such means includes passive or forced cooling either by air, or liquid, such as water, as is known.

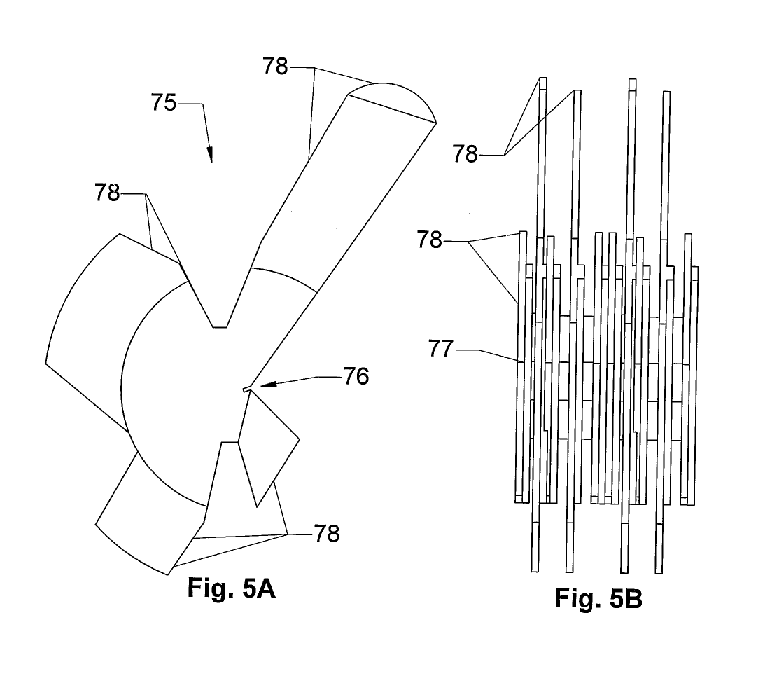

Reference is now made to FIGS. 5A and 5B in which two different side looking views of passive heat-sink 75 according to a preferred embodiment of the present invention are respectively shown. By means of such passive heat sink thermal waste is transferred to the ambient air at no additional operational cost. Groove 76 disposed at the frontal face of heat-sink body 77 is adapted for mounting a CPV array such that a good thermal connection exists between the CPV array and body 77. The faces of these CPV cells constitute the inlet of this receiver. The receiver is such mounted onto a mounting frame that its inlet is located at the outlet of the FECFHD. Fins 78 are such disposed to maximize the convection of ambient air. Obviously the dimensions of the heat sink and its various fins reflect on its cooling efficiency. However mounting such passive heat sink close to the optical concentrator is achievable such that it does not block the light propagating into the respective optical concentrator.

MHC Modules

An MHC module according to the invention consists of an optical subsystem having at least one optical concentrator and a plurality of heliostats respectively illuminating it, driving means for rotating the heliostats either independently or simultaneously and at least one local controller for carrying out sun tracking.

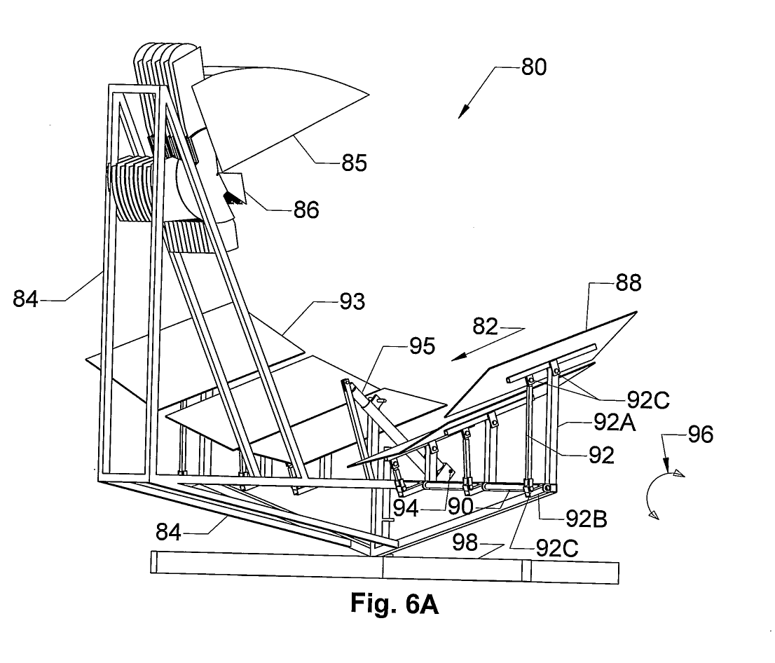

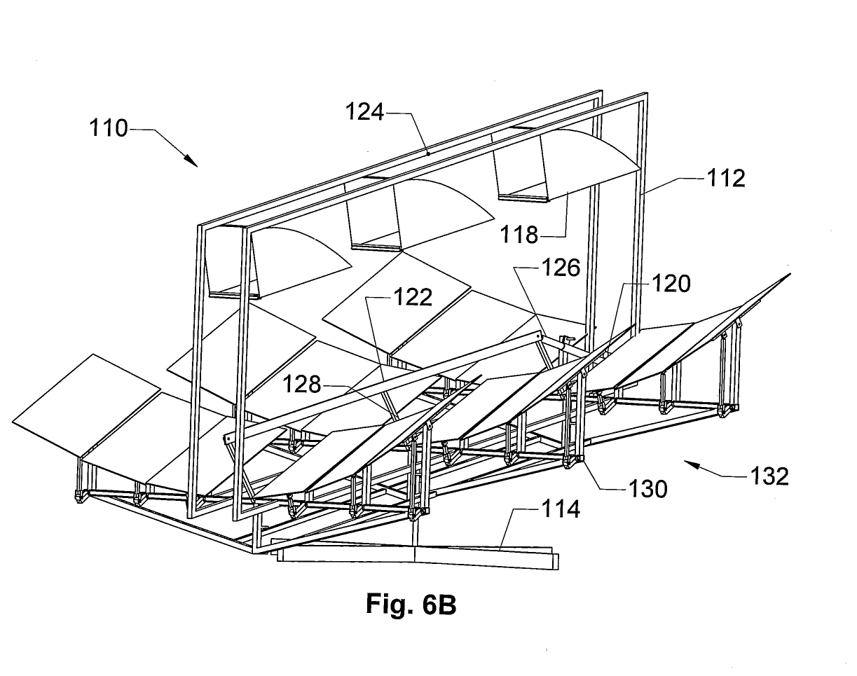

Reference is now made to FIGS. 6A and 6B in which two configurations of mounted MHC modules according to a preferred embodiment of the present invention are respectively shown. Mounted MHC module 80 has a single row of heliostats 82 that preferably consists of three pairs of heliostats mounted on a common frame 84. Optical concentrator 85 is attached to passive heat-sink 86 that is further attached to mounting frame 84. Each heliostat, such as heliostat 88 is hinged to mounting frame 84 by means of common shaft 90. Therefore all these heliostats have a common axis of rotation, which is the axis of axial shaft 90. The heliostats are respectively tilted by azimuth and elevation angles such that the level of the sun radiation reflected by each and every one of them into concentrator 85 is maximized. The lengths of and the angles between the bars supporting the reflective plates of the heliostats in row 82 such as bars 92, 92A and 92B connecting heliostat 88 to axial shaft 90 fix the different tilt angles of each heliostat. Therefore the reflective plate of heliostat 88 is respectively hinged to bars 92 and 92A by means of axes 92C. Similarly lateral connecting bar 92B is pivotally attached to bar 92 at its one end, whereas its other end is firmly fixed to axial shaft 90. Thus by rotating axial shaft 90 at any rotational angle each heliostat of row 82 changes its elevation such that all the reflective surfaces retains their synchronization in elevation angles and continue to be simultaneously directed towards the aperture of optical concentrator 85. Heliostat 93 is attached to axial shaft 90 at the same height above mounting frame 84 of its pairing heliostat 88 but is tilted and spaced from the optical axis of concentrator 85 symmetrically with heliostat 88 in the opposite directions. All the heliostats of row 82 are simultaneously rotated clockwise or counter clockwise by their respective rotational angles. Extending or extracting up to the same extent shaft 90 by means of driving motor 94, which is common to all the heliostats installed onto this module, effects rotations as shown by double arrow 96.

In FIG. 6B the optical subsystem of MHC module 110 is shown mounted on frame 112 and stabilized by means of base 114. MHC module 110 consists of three rows of simultaneously rotated heliostats providing for tracking the sun. Rotational movements are induced by means of driving motor 120 that simultaneously rotates the axial shaft of each row respectively. Such rotations are effected by translating connecting bar 122 back and or forth along the direction of upper frame 124 by means of respectively extracting or extending shaft 126. Exemplary vertical connecting bar 128 is pivotally attached to connecting bar 122 at one end and to axial shaft 130 at its opposite end for such simultaneously rotating all the heliostats of row 132.

Embodiment variants in which a group of heliostats collectively illuminating a common optical concentrator are individually equipped with driving motors and a local controller for independently tracking the sun are in accordance with the present invention. Such configurations of modules consisting of independently tracking heliostats are referred hereinafter as stand alone configurations. In such cases it is preferable to employ significantly larger heliostats, such as having widths and heights of a few meters. However manufacturing and maintaining an optical concentrator having an aperture of such dimensions is too complicated and expensive. Therefore combined optical concentrators are preferably employed. Obviously receivers for such configuration preferably consists of forced cooling since the dimensions of a passive heat sink of the invention cause a significant loss in the resulting concentration ratio.

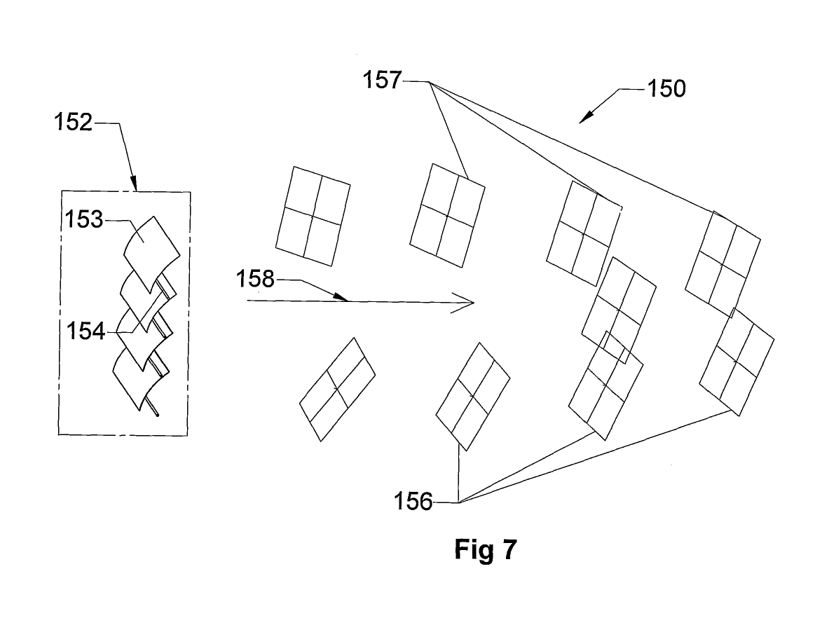

Reference is now made to FIG. 7 schematically showing layout of an MHC module having a stand-alone configuration 150 according to a preferred embodiment of the present invention. Combined optical concentrator 152 consisting of a two dimensional array of basic optical concentrators such as exemplary optical concentrator 153 whose focal region 154 is external to the adjacent concentrator. Combined optical concentrator 152 faces a plurality of heliostats such as heliostats 156 and 157, which preferably are symmetrically disposed relative to the optical axis 158 of combined optical concentrator 152. (Optical axis 158 is directed towards the north in the northern hemisphere.) The heliostats are densely arranged in front of concentrator 152, namely the spacing between adjacent heliostats are minimized conditioned that mutual blocking and or the level of mutual shadowing of adjacent heliostats, especially during morning and evening hours, are minimized. For such a purpose a shadowing measure defined by the time integral of the instantaneous accumulative shadowed and or blocked area of all the heliostats of MHC module 150 at any time during the daytime all year around is calculated. Obviously the geographical location of the site targeted for the installation of a MHC module imposes constraints such as slopes of the ground and or objects disposed within the area of the site on the process of selecting optimal arrangement. In consideration with the target location of the module, the arrangement of heliostats of which such calculated shadowing measure is minimal is selected.

Local Controller

A local controller according to the invention provides at least for sun tracking. Therefore a local controller has a sun-tracking device for sensing the instantaneous location of the sun along its orbit and is linked to the orientation sensors and driving motor or motors of a heliostat or a group of heliostats simultaneously controlled by it. A sun tracking device is typically provided with a search function which enables it to find the current location of the sun and continue in tracking it therefrom. Based on the instantaneous location of the sun and the current orientation of the heliostat or the group of heliostats, the controller activates a driving motor or motors to rotate respective heliostats, such that their instantaneous orientations comply with the instantaneous location of the sun. Optionally the same local controller or an additional controller provides for monitoring the status, as well as for controlling the operation of the various components, of an MHC module, such as the temperature of the CPV cells array of a receiver or its environmental conditions.

MHC System

An MHC system according to the invention provides for converting the electromagnetic energy of the sun into a different form of energy that can be further utilized. MHC system according to a preferred embodiment of the present invention consists of at least one mounted and or having a stand-alone configuration MHC module having a receiver including a CPV cell array. A MHC system further includes a central controller that is linked to all the local controllers of all the MHC modules of the system. The central controller monitors, controls, synchronizes and harmonizes the operation of all the modules to provide the electric power generated as is required.

The number of heliostats of a single MHC module and the MHC modules are arranged in such layout that is defined according to the present invention by considering maximizing optical efficiency, minimizing land use, minimizing mutual shadowing of the heliostats and preventing mutual blocking of the line of sight from the heliostats to the concentrator aperture. For small-scale power systems in the power range of several kilowatts a single mounted MHC module can provide such power. Large-scale MHC systems of the invention typically include a combination of mounted MHC modules and modules having a stand-alone configuration.

### EXAMPLE

The concentrating ratio of an optical concentrator and a mounted MHC module having one row of 6 heliostats, in accordance with a preferred embodiment of the present invention was analysed by way of simulation. The computations were carried out employing ray tracing. The physical model of the concentrator consists of a parabolic cylindrical reflective back wall, two opposing reflective sidewalls and the area of its aperture is 1 meter, complying with the apertures of the heliostats. Distortions of the reflective surfaces were introduced considering practical limitations of manufacturing, as well as inaccuracies in the mutual orientations of the heliostats and sun tracking errors were taken into account. A primary concentrating ratio in the range of 80-100 and a concentration ratio of 480-500 suns have been substantiated.

1. A multi heliostat concentrating (MHC) module comprising
At least one optical concentrator for converging sun radiation impinging on said aperture into a focal region, said optical concentrator has an aperture, an optical axis and a focusing reflective back wall;
a plurality of heliostats for reflecting said sun radiation upon said aperture of said at least one optical concentrator;
a receiver for converting a portion of energy of said sun radiation into another form of energy, and
wherein said receiver has a receiver inlet, and wherein said receiver inlet is such disposed that it is illuminated by a portion of said converged sun radiation.

2. A MHC module as in claim 1, wherein said heliostats are symmetrically disposed relative to said optical axis of said at least one optical concentrator.

3. A MHC module as in claim 1, wherein said optical concentrator has a reflective sidewall.

4. A MHC module as in claim 3, wherein said optical concentrator further has a focus error corrector and flux homogenizing device (FECFHD).

5. A MHC module as in claim 4, wherein a sidewall of said FECFHD is concaved.

6. A MHC module as in claim 4, wherein said FECFHD has an inlet and an axis, and wherein said inlet is inclined relative to said axis.

7. A MHC module as in claim 4, wherein said FECFHD has an inlet having a parabolic cylindrical surface.

8. A MHC module as in claim 4, wherein said FECFHD has an inlet having cylindrical surface.

9. A MHC module such as in any of claims 7 or 8, wherein said inlet of said FECFHD is coated with an anti-reflecting coating material.

10. A MHC module as in claim 1, wherein the number of said heliostats is even.

11. A MHC module as in claim 4, wherein said receiver comprises at least one concentrated photovoltaic cell disposed at the outlet of said FECFHD.

12. A MHC module as in claim 1, wherein at least two of said heliostats are mounted on a common mounting frame.

13. A MHC module as in claim 12, wherein said at least two heliostats are rotatable around a common axis of rotation.

14. A MHC module as in claim 12, wherein said at least two heliostats are simultaneously rotated by means of at least one common driving motor.

15. A MHC module as in claim 1, further comprising at least one local controller for tracking the sun.

16. A MHC module as in claim 15, linked to a central controller for monitoring the status of at least said local controller.

17. A MHC module as in claim 1, wherein said receiver further comprises a passive heat sink.
